(19) United States
(12) Patent Application Publication
(10) Pub. No.: US 2023/0347637 A1
(43) Pub. Date: Nov. 2, 2023

(54) CARRIER SUBSTRATE, METHOD FOR PRODUCING A CARRIER SUBSTRATE, AND METHOD FOR TRANSFERRING A TRANSFER LAYER FROM A CARRIER SUBSTRATE TO A PRODUCT SUBSTRATE

(71) Applicant: EV Group E. Thallner GmbH, St. Florian am Inn (AT)

(72) Inventor: Jurgen Burggraf, St. Florian am Inn (AT)

(73) Assignee: EV Group E. Thallner GmbH, St. Florian am Inn (AT)

(21) Appl. No.: 17/918,224

(22) PCT Filed: Apr. 20, 2020
(86) PCT No.: PCT/EP2020/061027

§ 371 Date: Oct. 11, 2022

(51) Int. Cl. B32B 37/00; C23C 16/01; C23C 16/26; C23C 16/02; C23C 14/00; C23C 14/02; C23C 14/06; C30B 25/18; C30B 23/02; C30B 29/02

(52) U.S. Cl. CPC B32B 37/025; C23C 16/01; C23C 16/26; C23C 16/0272; C23C 14/0005; C23C 14/024; C23C 14/0605; C30B 25/18; C30B 23/025; C30B 29/02

(57) ABSTRACT

The invention relates to a carrier substrate for transferring a transfer layer from the carrier substrate onto a product substrate and a method for the production of a carrier substrate and a method for transferring a transfer layer from a carrier substrate onto a product substrate.

### FIELD OF THE INVENTION

The invention describes a carrier substrate, a method for producing a carrier substrate and a method for transferring a transfer layer from a carrier substrate to a product substrate. The transfer layer, in particular a graphene layer, is first arranged on the carrier substrate, in particular the transfer layer has been generated or grown on a layer of the carrier substrate, and is transferred by the method for the transfer to a product substrate.

### BACKGROUND OF THE INVENTION

Layer transfer processes already exist in the prior art. These processes are used to transfer very thin transfer layers, in particular those with thicknesses in the micrometre or even nanometre range, from one substrate onto another substrate. Very many of these layers can only be produced on a specific first surface, which however is not at the same time intended to be part of the subsequent functional component. The layer thus has to be transferred from the first surface onto a second surface.

One of the most widely known layer transfer processes in the semiconductor industry is the SmartCut™ process. In this process, ions, in particular hydrogen ions, are fired into a first, monocrystalline substrate. The penetration depth of the hydrogen ions can be controlled by the kinetic energy and amounts to only several nanoinetres. The hydrogen ions remain in the first substrate until the substrate has been bonded to a second, oxidised substrate. A thermal process then ensures that the hydrogen atoms combine to form water molecules and a separation of the first, monocrystalline substrate takes place along the surface in which the hydrogen ions have collected. A triple layer structure is obtained, in which the oxide is enclosed between two other materials, usually silicon. The transferred layer of the first substrate is very thin and above all monocrystalline. The oxide layer lying beneath the latter then has favourable effects on components with high switching frequencies, in particular transistors.

Attempts have been made in the industry for several years to produce graphene on large areas. There are a number of methods for producing graphene in the prior art. Graphene flakes can already be produced industrially by the ton. These graphene flakes are however of secondary importance for the semiconductor industry, since they are far too small and mainly arise through wet-chemical processes, in particular in solution, and not on substrate surfaces. It is desired to produce a graphene layer either at the wafer level, i.e. over the entire area of a wafer, or in a targeted manner at an already existing topology of a wafer. The production of a graphene layer at wafer level, however, appears to be the most promising.

The greatest problem is in producing graphene layers or other sensitive layers to be transferred in a cost-effective, rapid, large-area and defect-free manner. Experience has shown that the large-area growth of graphene layers preferably takes place on an, in particular monocrystalline, metal surface.

The problem is, however, in the fact that the surfaces on which graphene is to be grown over a large area correspond in very rare cases to the surfaces on which the graphene is to be structured and used. The graphene thus has to be transferred from a first surface, a production surface, onto a second surface, a use surface. In the transfer, use is usually made of debonding means, in particular lasers, the influence whereof, in particular electromagnetic radiation, could destroy or damage the transfer layer or the graphene layer.

### SUMMARY OF THE INVENTION

It is therefore an aim of the present invention to provide a carrier substrate, a method for producing a carrier substrate and a method for transferring a transfer layer from the carrier substrate to a product substrate, which at least partially overcome, in particular completely overcome the drawbacks found in the prior art. In particular, it is an aim of the invention to specify an improved carrier substrate and a carrier substrate production method and a method for the transfer, in order to transfer a transfer layer from the carrier substrate onto a product substrate. Furthermore, it is in particular an aim of the present invention to provide a carrier substrate and a method for transferring a transfer layer from the carrier substrate to a product substrate, wherein the transfer layer is not destroyed or damaged, in particular by electromagnetic radiation.

The present invention is described herein with the features of the coordinated claims. Advantageous developments of the invention are specified in the sub-claims. All combinations of at least two features specified in the description, in the claims and/or the drawings also fall within the scope of the invention. In the stated value ranges, values lying within the stated limits should also be deemed to be disclosed as limiting values and can be claimed in any combination.

In the following text, a transfer layer or a layer to be transferred, in particular in the form of a graphene layer, is understood to mean the layer on the carrier substrate that is to be transferred onto the product substrate. In particular, the transfer layer has been grown on a protective layer or a growth layer of the carrier substrate. Protective layer and growth layer are thus used synonymously in the subsequent text.

The growth layer and the protective layer can however be two different layers. The growth layer is in contact with the transfer layer, so that the protective layer is located between the growth layer and the carrier substrate. In the subsequent text, it is assumed for the sake of simplicity that the growth layer and the protective layer are identical. This state is also the more sensible economically, since in this case only one layer has to be deposited and the process costs can thus be kept lower.

Accordingly, the invention relates to a carrier substrate for transferring a transfer layer from the carrier substrate to a product substrate, comprising at least the following layers in the following sequence:
a carrier base substrate,
a protective layer and
a transfer layer,
   wherein the transfer layer is grown on the protective layer.

The carrier substrate comprises at least the aforementioned layers in the aforementioned sequence. It is also conceivable, however, that further intermediate layers, in particular with specific functions, are arranged between and/or on the aforementioned layers. In particular, the protective layer can for example comprise a plurality of individual layers, which each protect the transfer layer. The protective layer acts as a barrier for the protection of the transfer layer, in particular against influences which act for the transfer and could damage or destroy the transfer layer. In order to transfer the transfer layer from the carrier substrate to the product substrate, the adhesive property in the region between the protective layer and the transfer layer in particular is reduced, wherein the protective layer shields the layer to be transferred. As a result of this layer structure of the carrier substrate, the transfer of the transfer layer can advantageously be carried out in a straightforward and efficient manner, wherein the transfer layer is not damaged, since the latter is protected by the protective layer. Furthermore, as a result of the dual function of the protective layer as a barrier and as a growth layer for the transfer layer, cost-effective production on an industrial scale is enabled.

The invention also relates to a method for producing a carrier substrate for transferring a transfer layer from the carrier substrate onto a product substrate, with the following steps:
i) provision of a carrier base substrate,
ii) application of a protective layer on the carrier base substrate,
iii) growing of a transfer layer, in particular a graphene layer, on the protective layer.

The method for producing a carrier substrate makes provision such that a transfer layer is grown on a protective layer. The protective layer can serve on the one hand as protection of the transfer layer during a transfer of the transfer layer, and also as the location for the generation or growth of the transfer layer. The protective layer thus has a dual function, so that an additional layer can be spared in the production. In addition, by means of the carder substrate comprising the protective layer, a subsequent transfer is possible without impairing the transfer layer. Advantageously, it thus becomes possible to easily separate the location of the generation or growth of the transfer layer from the use on the product substrate.

Furthermore, the invention relates to a method for transferring a transfer layer from the carrier substrate or a carrier substrate produced according to the method for producing a carrier substrate onto a product substrate, wherein
the carrier substrate is contacted by the product substrate, so that the transfer layer is facing the product substrate, and
wherein at least one debonding means acts on the carrier substrate, so that the transfer layer together with the protective layer is detached from a carrier base substrate.

The method of transferring the transfer layer thus advantageously permits a straightforward and efficient transfer of the transfer layer from one surface onto another surface, in particular the transfer from a production surface onto a use surface.

The detachment is enabled by the action of the at least one debonding means, in particular in the form of a laser, preferably in the form of an infrared laser, wherein the protective layer protects the transfer layer against the influences of the at least one debonding means or shields the transfer layer against the influences, so that the transfer layer is not damaged. In particular, provision is made such that the transfer layer together with the protective layer is detached from the carrier substrate and the protective layer is subsequently removed. The carrier substrate is contacted by the product substrate, so that a relative movement between the contacting surfaces is advantageously no longer possible. Before a contact is made, the carrier substrate and the product substrate are aligned with one another, in particular by an alignment of respective substrate holders. For the alignment, use is made in particular of alignment marks, which are applied on the carrier substrate and/or the product substrate, for an alignment that is as exact as possible.

Consequently, the transfer of a transfer layer onto a product substrate is advantageously enabled in a straightforward and efficient manner. Particularly advantageously, the transfer layer is not damaged or destroyed by the action of the debonding means. The generation or growth of the transfer layer has been carried out beforehand on the carrier substrate. The transfer layer can thus advantageously be detached from the place of its generation or its growth on the carrier substrate, in particular on the protective layer, and can be arranged on the product substrate.

In a preferred embodiment of the carrier substrate, provision is made such that the transfer layer is a graphene layer. The graphene layer is arranged on the protective layer and is protected by the protective layer. Since provision is made such that the carrier substrate designed to transfer the graphene layer is debonded during the transfer together with the protective layer from the carrier base substrate and the graphene layer is thus separated from the carrier substrate, the means for the debonding, in particular in the form of electromagnetic radiation, cannot damage or destroy the graphene layer. The carrier substrate is thus predestined for the transfer of a graphene layer. The carrier substrate advantageously enables the straightforward and efficient production and the transfer of the graphene layers in large quantities, instead of as previously only on the laboratory scale. A particular advantage includes the fact that the graphene layer is grown as a transfer layer on the protective layer.

In another preferred embodiment of the carrier substrate, provision is made such that a roughness of the protective layer, in particular of the surface facing the transfer layer, is less than 100 μm, preferably less than 10 μm, still more preferably less than 1 μm, most preferably less than 100 nm, with utmost preference less than 10 nm. It is only by keeping the roughness of the growth layer as small as possible that the generation or the growth of the transfer layer in particular is made possible in the first place. Particularly thin transfer layers, in particular graphene layers, have to be grown on very flat, clean surfaces. The transfer layer is thus generated on the layer by which the latter is protected even before the influences of the debonding means acting during the transfer. The protective layer is preferably recrystallised during its production before the growth of the transfer layer, so that the growth of the transfer layer, in particular of the graphene layer, is additionally simplified or improved.

In another preferred embodiment of the carrier substrate, provision is made such that the carrier substrate comprises at least one release layer arranged between the carrier base substrate and the protective layer. The release layer can advantageously predetermine the precise location of the detachment of the transfer layer at the carrier base substrate. Furthermore, a detachment along the release layer can advantageously take place in a straightforward and efficient manner.

Through the design of the release layer, the required adhesive force between the carrier base substrate and the protective layer can also advantageously be predetermined. In particular, it is possible to predetermine by the design of the release layer the influences under which a detachment of the transfer layer should be possible.

In another preferred embodiment of the carrier substrate, provision is made such that the transfer layer can be detached from the carrier base substrate together with the protective layer by means of a debonding means acting on the release layer and/or on a release area. The debonding means acts/act on the carrier substrate when a debonding process is to be carried out. The release layer or release area and the debonding means are geared to one another. A release layer is a separate layer of material, whereas a release area is defined by the contact area between the carrier base substrate and the protective layer. A detachment in the release area can take place for example by the expansion of materials introduced into the contacting surface areas. A release area does not therefore represent a separate layer of the carrier substrate, but in particular performs the same function. When the debonding means acts on the release area or on the release layer, the adhesive properties of the release layer or the adhesive properties of the protective layer which are in contact and the carrier base substrate are in particular changed, so that the protective layer together with the transfer layer can be detached from the carrier base substrate. A transfer of the transfer layer from the carrier substrate to a product substrate can thus be carried out in a particularly straightforward and efficient manner.

In another preferred embodiment of the carrier substrate, provision is made such that the protective layer comprises a material with a solubility for carbon. If the protective layer is a material with a particularly high degree of solubility for carbon, the transfer layer, in particular made of graphene, can be generated or grown by heating and cooling on the protective layer. The carbon is thereby deposited on the surface of the protective layer and the transfer layer is produced on the carrier substrate. By means of the particular and advantageous layer structure of the carrier substrate, the generated transfer layer can now be transferred onto a product substrate in a straightforward and efficient manner.

In another preferred embodiment of the carrier substrate, provision is made such that the protective layer is designed impermeable for electromagnetic radiation. If electromagnetic radiation is used for the debonding or for reducing the adhesive properties of the release layer, for example a laser, the protective layer can absorb the radiation and thus prevent damage or destruction of the transfer layer. In this embodiment, the carrier base substrate is preferably at least partially permeable for electromagnetic radiation. For example, the carrier base substrate is made of glass, preferably of sapphire glass.

In another preferred embodiment of the carrier substrate, provision is made such that a contact layer, in particular made of a dielectric material, preferably of silicon oxide, is arranged on the side of the transfer layer facing away from the protective layer. When the transfer to the product substrate takes place, such a contact layer enables simpler and reliable contacting. In addition, by using a dielectric material, for example silicon oxide, for the contact layer, short circuits in the product substrate can be prevented or an electrical conduction between the product substrate and the transfer layer can be permitted only at desired points. A further contact layer can also be arranged on the product substrate. The contact layer and the further contact layer of the product substrate are preferably made of the same material and enable particularly straightforward contacting between the carrier substrate and the product substrate.

In another preferred embodiment of the carrier substrate, provision is made such that the protective layer is a monocrystalline metal layer, preferably made of nickel. The generation or growing of the transfer layer advantageously takes place on a monocrystalline material. By using a monocrystalline metal layer, the transfer layer can advantageously be grown on the protective layer. At the same time, the monocrystalline metal layers are also suitable for protecting the transfer layer against the influences of an electromagnetic debonding means, for example a laser. The protective layer made of nickel is most preferable, since a graphene layer can be generated or grown particularly well on such a nickel-base layer.

In another preferred embodiment of the carrier substrate, provision is made such that the transfer layer is generated on the protective layer. According to this embodiment, the layer to be transferred is generated directly on the protective layer. The transfer layer is thus advantageously arranged directly on the protective layer, so that the transfer layer is protected directly by the protective layer against influences acting from the other side of the protective layer. The particular layer structure of the carrier substrate enables the straightforward and efficient transfer of the transfer layer from the carrier substrate to the product substrate.

In another preferred embodiment of the carrier substrate, provision is made such that the protective layer is at the same time designed as a growth layer for the transfer layer, so that the transfer layer can be grown on the protective layer. In the embodiment, the protective layer performs two functions. The first function is the protection function of the protective layer, which means in particular that the protective layer protects the transfer layer against the influences of the debonding means. The second function enables the growing of a transfer layer on the protective layer, which in this case can be used at the same time as a growth layer. Advantageously, only one layer is thus required for the protection and for the generation of the transfer layer, in particular of the graphene layer. It is also conceivable that the protective layer is constituted by a plurality of layers. The layer or layers facing the release layer are designed as protective layers. The layer or layers facing away from the release layer enable the generation of a transfer layer. The dual function of the protective layer is thus achieved by two or more layers, wherein the protective layer comprises at least two layers. Preferably, however, one layer forms the protective layer, which simultaneously enables the protection function and the generation of the transfer layer.

In another preferred embodiment of the carrier substrate, provision is made such that the transfer layer can be detached from the carrier base substrate together with the protective layer by means of at least one debonding means acting on the release layer or a release area. The debonding means, preferably in the form of a laser, acts on the release layer, so that the adhesive properties of the release layer are diminished and the transfer layer together with the protective layer can be detached from the carrier substrate. The debonding means preferably acts on the release layer. Further influences arising from the debonding means are reduced, preferably prevented, by the protective layer. The protective layer preferably acts for the transfer layer as a barrier against the influences arising from the debonding means. In this way, debonding of the transfer layer can advantageously be carried out without damaging the transfer layer.

In a preferred embodiment of the method for producing a carrier substrate, provision is made such that the protective layer is recrystallised before the growing of the transfer layer in step iii). On the protective layer preferably exhibiting a very low degree of roughness, its function as a growth layer can thus be performed still better. The growth of the transfer layer, in particular of a graphene layer, on the protective layer is thus simplified or improved.

In an embodiment of the method for producing a carrier substrate, provision is made such that the carrier base substrate is coated with a release layer before the application of the protective layer in step ii), so that the protective layer is deposited on the release layer. In a subsequent transfer of the generated transfer layer, a detachment can thus advantageously be carried out in a straightforward manner. In addition, the location of the detachment can advantageously be predetermined by the application of a release layer.

In a preferred embodiment of the method for producing a carrier substrate, provision is made such that a contact layer is deposited on the transfer layer on the side facing away from the protective layer. The contact layer advantageously simplifies the bonding process carried out during the transfer of the transfer layer. Furthermore, the contact layer can also serve for better contacting with the product substrate. Furthermore, a contact with the transfer layer in specific predetermined areas can be enabled by means of a functionalised contact layer, for example by means of electrically conductive areas.

In a preferred embodiment of the method for producing a carrier substrate, provision is made such that the protective layer is designed simultaneously as a growth layer for growing the transfer layer on the protective layer and the transfer layer is grown on the protective layer. The protective layer thus advantageously performs the protection function and enables the generation of the transfer layer on the protective layer. Advantageously, therefore, only one layer is used. It would however also be conceivable for the protective layer to be built up from two or more layers. The layers facing the release layer or the layer facing the release layer is then designed for protection against the influences of the debonding means. The further layer or further layers enable, as a growth layer, the generation of the transfer layer. It is preferable, however, that the protective layer is designed as one layer with a dual function. The method for producing a carrier substrate can thus advantageously be carried out in a straightforward and efficient manner.

In another preferred embodiment of the method for producing a carrier substrate, provision is made such that a contact layer is deposited on the transfer layer. The contact layer is preferably made of a dielectric material, particularly preferably of silicon oxide. Subsequently, short circuits in the product substrate can thus be prevented. Furthermore, contacting of the carrier substrate with the product substrate can be carried out particularly easily and reliably.

In a preferred embodiment of the method for transferring a transfer layer, provision is made such that the carrier substrate is contacted by the product substrate via a contact layer applied on the transfer layer or the carrier substrate is contacted by a further contact layer of the product substrate applied on the product base substrate via a contact layer applied on the transfer layer. The product substrate thus comprises a further contact layer. The contact layer is preferably made of a dielectric material, particularly preferably of silicon oxide. When the carrier substrate also comprises a contact layer on the transfer layer, the contact layer of the carrier substrate and the further contact layer of the product substrate are particularly preferably made of the same material. Contacting during the transfer can thus take place in a particularly straightforward and efficient manner. In addition, short circuits are prevented by the contact layers.

In another preferred embodiment of the method for transferring a transfer layer, provision is made such that the transfer layer is bonded with the product substrate or a contact layer arranged on the transfer layer is bonded with the product substrate. The transfer layer is bonded with the product substrate, as a result of which the transfer is completed.

The bonding process is preferably split up into a pre-bond and a subsequent permanent bond. With the pre-bond, a relatively weak connection theoretically detachable again without destruction is produced between the two substrates, which is preferably based on surface effects. In this case, hydrophilic surfaces are particularly advantageous. The subsequent permanent bond is characterised by a reinforcement of the connections produced in the pre-bond. The permanent bond is preferably achieved by a raised temperature. The temperature should however be as low as possible, in order to reduce or preferably completely prevent possible damage to the transfer layer or to plant parts that may be present. The temperature in the permanent bonding is therefore preferably less than 300° C., preferably less than 200° C., still more preferably less than 100° C., most preferably less than 50° C., with utmost preference room temperature. Such pre-bonds and permanent bonds are known to expert in the field.

The protective layer is detached from the transfer layer in particular before, during or after the bonding of the transfer layer and the product substrate. By means of the method, a transfer of a defect-free, large-area and sensitive transfer layer can take place in a particularly straightforward and efficient manner. The transfer of a graphene layer onto the product substrate is particularly preferred. Functional components can have been previously inteurated into the product substrate itself, in particular through-contact vias can be present, so that a targeted and desired electrical conductivity between the product substrate and the transfer layer is possible only in these areas.

In the following, the term growth layer is used for protective layer. Since in the majority of cases the protective layer is designed for the protection and for the generation or growing of the transfer layer, the terms growth layer and protective layer are referred to in the following as growth layer. This does not however mean just a single growth layer without the protection function, but on the contrary a growth layer is a protective layer on which the transfer layer can be grown or generated.

A particular aspect of the inventive idea includes the specification of a method with which the growth or generation, the transfer and the debonding of a single layer or a graphene layer to be transferred from a production surface of a carrier substrate onto a use surface of a product substrate can be carried out. The underlying idea includes the fact that a layer system, comprising a carrier base substrate, a release layer, a growth layer, the graphene layer (transfer layer), and preferably a dielectric layer, is produced in a well-defined sequence, so that the layer transfer can be carried out without problem.

A further aspect of the invention makes provision to produce a very special layer structure on a carrier substrate, the individual layers of which perform different functional tasks. In particular, a release layer is used for the detachment of the graphene layer from the carrier substrate. A growth layer or protective layer is used for the growth and at the same time for the protection of the transfer layer or the graphene layer.

The carrier base substrate, on which the layer to be transferred or the graphene can be produced, generally differs from the product base substrate, on which the layer to be transferred or the graphene is to be used. The process for the production of the transfer layer or the graphene growth is separated from the location for the use of the transfer layer or the graphene use. The production of such a sensitive transfer layer or graphene layer is correspondingly flexible and cost-effective.

The carrier substrate and the method for transferring a transfer layer can in principle be used for the transfer of any kind of layer to be transferred or transfer layer. By way of example, however, the transfer of a graphene layer as a transfer layer is described, since a transfer of such a monoatomic layer must meet particular requirements and has not hitherto been able to be implemented in this way in the industry.

The method according to the invention is therefore in no respect limited to the transfer of a graphene layer. For example, the transfer layer can also be another carbon-based, in particular monoatomic layer.

The transfer layer is preferably made from at least one of the following material classes or materials.
2D layer material, in particular
   Graphene
   Graphyne
   borophene
   germanene
   silicene
   Si₂BN
   gallenene
   stanene
   plumbene
   phosphorene
   antimonene
   bismuthene
2D supercrystals
compounds
   graphane
   boronitrene
   borocarbonitride
   germanane
   germanium phosphide
   transition metal dichalcogenide
   MXenes
layer materials with different element composition, in particular
   MoS2, WS2, MoSe2, hBN, Ti4N3, Ti4AIN3
Van der Wallis hetereo-structures, in particular
   MoS2-G, MoS2-hBN, MoS2-hBN-G
metal, in particular
   Cu, As, Au, Al, Fe, Ni, Co, Pt, W, Cr, Pb, Ti, Ta, Zn, Sn
semiconductors, in particular
   Ge, Si, Alpha-Sn, B, Se, Te,
compound semiconductors, in particular
   GaAs, GaN, InP, InxGal-xN,Sb, InAs, GaSb, AIN, InN, GaP, BeTe, ZnO, CuInGaSe2, ZnS, ZnSe, ZnTe, CdS, CdSe, CdTe, Hg(1-x)Cd(x)Te, BeSe, HgS, AlxGal-xAs, GaS, GaSe, Gale, InS, InSe, InTe, CuInSe2, CuInS2, CuInGaS2, SiC, SiGe
ceramic
polymer
further materials
   SiO₂
   Si₃N₄
   MnO₂
   TBAₓH_{(1.07-x)}Ti_{1.73}O₄*H2O
   CoO₂
   TBAₓH₍₁₋ₓ₎Ca₂Nb₃O₁₀
   Bi₂SrTa₂O₉
   Cs₄W₁₁O₃₆⁻²
   Ni(OH)_{5/3}DS_{1/3}
   Eu(OH)_{2.5}(DS)_{0.5}
   Co_{2/3}Fe_{1/3}(OH)₂^{1/3+}
   [Cu₂Br(IN₂)]ₙ]

The transfer layer is most preferably a layer of graphene.

The method for transferring the transfer layer requires in particular a product substrate and a carrier substrate. The product substrate and carrier substrate generally comprise a product base substrate and a carrier base substrate. A plurality of layers can generally be deposited on the product base substrate andlor the carrier base substrate.

The product base substrate and the carrier base substrate can in principle be made from any material, but preferably belong to one of the following material classes:
1. Semiconductor material, in particular
   1.1 Ge, Si, Alpha-Sn, B, Se, Te
2. Metal, in particular
   2.1 Cu, Ag, Au, Al, Fe, Ni, Co, Pt, W, Cr, Pb, Ti, Ta, Zn, Sn
3. Compound semiconductors, in particular
   3.1 GaAs, GaN, InP, InxGa1-xN, InSb, InAs, GaSb, AIN, InN, GaP, BeTe, ZnO, CuInGaSe2, ZnS, ZnSe, ZnTe, CdS, CdSe, CdTe, Hg(1-x)Cd(x)Te, BeSe, HgS, AlxGa1-xAs, GaS, GaSe, GaTe, InS, InSe, InTe, CuInSe2, CuInS2, CuInGaS2, SiC, SiGe
4. Glass, in particular
   4.1 metallic glasses
   4.2 non-metallic glasses, in particular
      4.2.1 organic non-metallic glasses
      4.2.2 inorganic non-metallic glasses, in particular
         4.2.2.1 non-oxidic glasses, in particular
         4.2.2.1.1 halogenide glasses
         4.2.2.1.2 chalkoizenide glasses
         4.2.2.2 oxidic glasses, in particular
         4.2.2.2.1 phosphatic glasses
         4.2.2.2.2 silicate glasses, in particular
         4.2.2.2.2.1 aluminosilicate glasses
         4.2.2.2.2.2 lead silicate glasses
         4.2.2.2.2.3 alkali silicate glasses, in particular
         4.2.2.2.2.3.1 alkali-earth alkali silicate glasses
         4.2.2.2.2.4 borosilicate glasses
         4.2.2.2.2.5 quartz glass
         4.2.2.2.3 borate glasses, in particular
         4.2.2.2.3.1 alkali borate glasses
   4.3 materials which are referred to as glasses but are not glasses
      4.3.1 sapphire glass.

The substrates are described in greater detail below.

### Product Substrate

In a first embodiment, the product substrate comprises only the product base substrate. It thus comprises no coating at all. A product base substrate without layers can serve in particular as a starting layer for a transferred izraphene layer, which is then to be structured as a conductive layer. A further substrate can then be bonded to this conductive layer. The provision of individual chips would also be conceivable. The most preferred product base substrate is a wafer, in particular a silicon wafer.

In a second embodiment, a layer is present on the product base substrate, which is referred to below as a contact layer. The contact layer is preferably a dielectric layer, most preferably a silicon oxide layer. The layer is called a contact layer, since it is contacted by the transfer layer to be transferred, in particular a graphene layer, or a layer deposited thereon in a subsequent process step. The contact layer is preferably a dielectric layer, most preferably an oxide, with utmost preference a silicon oxide. The oxide can be produced thermally or can grow native in an oxygen atmosphere. Such a dielectric layer can facilitate the transfer process of the transfer layer or the graphene layer or may be necessary for the desired end result.

In a third embodiment, functional units, in particular microchips, memories, MEMs, LEDs etc. have previously been produced in the product base substrate. In a very particularly preferred extended embodiment, the product base substrate is coated with a contact layer after the, in particular functional, units have been produced. In further process steps, the dielectric contact layer is then opened, in particular lithographically, above the contacts of the functional units. The openings thus arising can then be filled in further process steps with a conductor, in particular a metal. These through-contact vias are referred to in the semiconductor industry as TSVs (also known as “through silicon vias”). The contact layer thus becomes a hybrid layer. The through-contact vias represent the electrical areas, the dielectric layer surrounding them representing the dielectric areas. In subsequent process steps, the transfer layer or the graphene layer is then transferred onto the contact layer and a contact is thus created between the graphene and the functional units via the TSVs. It is also conceivable that the contact layer is dispensed with and only the product base substrate with the functional units is used to transfer the transfer layer thereon.

By means of a contact layer, it is possible to select a material with certain properties which the product substrate itself does not possess. For example, silicon represents an intrinsic semiconductor and therefore has a conductivity, even though only very small, also at room temperature. The surface onto which the transfer layer or the graphene layer is transferred should in many cases be dielectric, in order to prevent a short circuit after the restructuring of the material of the transfer layer, graphene. Since silicon can be oxidised with known methods, a silicon oxide is a preferred material for a dielectric layer.

A transfer layer, for example a graphene layer, can then be transferred onto one of the aforementioned product substrates with the aid of the method, which transfer layer can then be structured. In particular, the transfer layer is structured such that it correspondingly connects these conductive contacts of the functional units, in particular via the TSVs,

The product base substrate is preferably a wafer, particularly preferably a silicon wafer.

### Carrier Substrate

The carrier substrate comprises at least one carrier base substrate, a growth layer and the transfer layer arranged thereon, in particular the previously generated izraphene layer. The layers are applied on the carrier substrate in a special sequence. The aforementioned layers necessarily have to be applied in the aforementioned sequence. It would be conceivable, however, for further layers to be located between the aforementioned layers, which are used in particular for other purposes. In particular, a release layer can be arranged between the carrier base substrate and the protective layer.

In a fiirst embodiment, the carrier substrate comprises at least one carrier base substrate, a release layer deposited thereon, a growth layer generated on the release layer and the transfer layer arranged thereon, in particular in the form of a graphene layer generated thereon.

The first layer is a release layer, the purpose of which includes being able to separate the carrier base substrate in the debonding process from the other layers.

The second layer is a growth layer, on which the transfer layer is arranged or the graphene layer is to be grown or generated. The growth layer can in principle have any morphology and grain structure, but is preferably monocrystalline. The growth layer is preferably a metal layer, in a very particularly preferred embodiment a metal layer with a solubility for carbon. The solubility for carbon should preferably diminish with falling temperature, so that prepitations, in particular at the surface of the growth layer, are enabled.

A particularly preferred advantageous characteristic feature of the growth layer or the protective layer includes the fact that it acts as a barrier for the dehonding method to be used. It prevents or reduces at least the passage of the influences, which are required for the debonding process at the release layer, but which should not act on the transfer layer or the graphene layer. They include heat input, but in particular the action of electromagnetic radiation, in particular laser radiation. The growth layer therefore acts not only as a location for the graphene growth, but also as a barrier between the graphene layer and the location of the debonding process, which takes place at the release layer. The feature of the protective layer particularly includes the fact that it is designed in relation to the employed dehonding process in such a way that, on the one hand, the generation of the transfer layer can take place, but the transfer layer is at the same time protected by the protective layer against an excessively strong influence of the debonding process.

The protective layer or the growth layer also has a roughness that is as low as possible. The roughness is indicated either as a mean roughness, a quadratic roughness or as an averaged roughness depth. The ascertained values for the mean roughness, the quadratic roughness and the averaged roughness depth generally differ for the same measurement section or measurement area, hut generally lie in the same order of magnitude range. Consequently, the following numerical value ranges for the roughness are to be understood either as values for the mean roughness, the quadratic roughness or for the averaged roughness depth. The roughness of the growth substrate is less than 100 μm, preferably less than 10 μm, still more preferably less than 1 μm, most preferably less than 100 nm, with utmost preference less than 10 nm.

The roughness of the release layer is also as low as possible, in particular in order to keep the roughness of the growth layer formed on the release layer as low as possible. The roughness of the release layer is less than 100 μm, preferably less than 10 μm, still more preferably less than 1 μm, most preferably less than 100 nm, with utmost preference less than 10 nm. The release layer can in principle be made of any material which leads to a separation from the growth layer with the aid of the aforementioned debonding methods. Preferably, however, the release layer is not a polymer, since a polymer would cause an unnecessary, undesired contamination of the plant used in the process according to the invention. The release layer is thus preferably made of a metal, an alloy or a semiconductor material. For the sake of completeness, the most important material classes that can be used as a release layer are listed.
1. Semiconductor material, in particular
   1.1 Go, Si, Alpha-Sn, B, Se, Te
2. Metal, in particular
   2.1 Cu, Ag, Au, Al, Fe, Ni, Co, Pt, W, Cr, Pb, Ti, Ta, Zn, Sn
3. Compound semiconductors, in particular
   3.1 GaAs, GaN, InP, InxGa1-xN, InSb, InAs, GaSb, AIN, InN, GaP, BeTe, ZnO, CuInGaSe2, ZnS, ZnSe, ZnTe, CdS, CdSe, CdTe, Hg(1-x)Cd(x)Te, BeSe, HgS, AlxGa1-xAs, GaS, GaSe, GaTe, InS, InSe, InTe, CuInSe2, CuInS2, CuInGaS2, SiC, SiGe
4. Polymers
   4.1 carbon-based polymers
   4.2 silicon-based polymers

The release layer is most preferably made of an epitaxially produced GaN layer. The GaN layer is generated epitaxially on the carrier substrate, in particular a sapphire substrate. A contaminating polymer layer can be dispensed with by using a very thin GaN layer.

In a further embodiment, the release layer is constituted as a release area, so that a release layer can be dispensed with if ions, preferably hydrogen ions, are implanted in the growth layer and/or the carrier substrate, which in the presence of a thermal load lead to damage to the growth layer and/or the carrier substrate. This process is known as the SmartCut™ process in the semiconductor industry, The release area with the introduced ions thus assumes the function of the release layer.

If the debonding process is a process in which electromagnetic radiation, in particular a laser, is used, a transmission of the electromagnetic radiation to the transfer layer can be prevented or at least reduced by the thickness of the protective layer. In this case, the protective layer is thicker than 1 nm, preferably thicker than 100 nm, still more preferably thicker than 1 μm, most preferably thicker than 100 μm, with utmost preference thicker than 1 mm.

If the debonding process is a process in which heat is used, the protective layer can be used that is made from a material which has a thermal conductivity as low as possible, in order to at least prolong the heat transport until the debonding process has ended. The thermal conductivity lies between 0.1 W/(m*K) and 5000 W/(m*K), preferably between 1 W/(m/K)and 2500 W/(m*K), still more preferably between 10 W/(m*K) and 1000 W/(m*K), most preferably between 100 W/(m*K) and 450 W/(m*K).

The third layer is the transfer layer or the graphene layer to be transferred, which is generated, laid down or deposited by any process.

In a second embodiment, at least one further layer, in particular a contact layer, is deposited on the graphene layer. The contact layer is preferably made of the same material or a very similar material to a contact layer of the product substrate, insofar as the product substrate also comprises a contact layer. The contact layer is thus preferably also an oxide, particularly preferably a silicon oxide. In particular, the application of an oxide as the last layer on the graphene layer has the advantage that the carrier substrate can be bonded, with the aid of a fusion bond, to the product substrate. The product substrate in this case preferably also comprises an oxide layer. It is thus particularly easy to produce the connection between the two substrates.

The contact layer is preferably hydrophilic. A measure for the hydrophibicity or hydrophilicity is the contact angle that is formed between a test liquid drop, in particular water, and the surface to be measured. Hydrophilic surfaces flatten the liquid drop, since the adhesion forces between the liquid and the surface dominate over the cohesive forces of the liquid, and therefore form smaller contact angles. Hydrophobic surfaces lead to a spherical shape of the liquid drop, since the cohesive forces of the liquid dominate over the adhesive forces between the liquid and the surface, The contact angle is less than 90°, preferably less than 45°, more preferably less than 30°, most preferably less than 10°, with utmost preference less than 5°. A hydrophilic contact layer serves in particular for a better and simpler transfer.

The carrier base substrate is preferably made of a material which has a property for the employed debonding method that is as optimum as possible. If the debonding process is to be carried out by means of heat, materials with a high thermal conductivity are recommended in order to transport the heat as quickly as possible to the release layer. The thermal conductivity lies between 0.1 W/(m*K) and 5000 W/(m*K), preferably between 1 W/(m*K) and 2500 W/(m*K), still more preferably between 10 W/(m*K) and 1000 W/(m*K), most preferably between 100 W/(m*K) and 450 W/(m*K).

A process for the transfer of the graphene layer is described below.

### Processes

### Carrier substrate production process

In a first process step of a production process for a carrier substrate, the carrier base substrate is coated with a release layer.

In a second process step of a production process for a carrier substrate, a growth layer is applied, in particular deposited, on the release layer. The growth layer is preferably monocrystalline. The production of a monocrystalline growth layer on an, in particular polymeric, release layer is virtually impossible. In a particular embodiment, therefore, the growth layer is not generated by a deposition process on the release layer, but is transferred by another layer transfer process onto the release layer. The SmartCut™ process would be conceivable here. Any other process for the layer transfer would also be suitable.

In a third process step of a production process for a carrier substrate, a transfer layer is arranged, preferably generated on the growth layer. The transfer layer is preferably a lzraphene layer, which is generated or grown. The growth of the graphene layer can take place by any known method from the prior art.

It would be conceivable, for example, for carbon atoms to have been dissolved at higher temperatures in the generated growth layer and for the system to be cooled in a further intermediate step, to such an extent that the solubility of the carbon in the material is fallen short of. Carbon is thus separated out, in particular also at the surface, and can form a graphene layer.

In another embodiment, the carbon is not located in the growth layer, but is fed to the growth layer from outside by means of suitable deposition processes. The use of molecular beam epitaxy, PVD or CVD processes etc., for example, is conceivable.

In an extension of the third process step, a further layer is deposited on the transfer layer or the graphene layer, said further layer serving in particular to optimise the contacting in subsequent process steps. This layer is therefore referred to as a contacting layer. The contacting layer is in particular an oxide layer and preferably made of the same material as a contact layer of the product substrate.

### Layer Transfer Process

The layer transfer process is described in detail in the following.

In a first process step, the carrier substrate is aligned relative to the product substrate. The alignment takes place mechanically and/or optically. Separate alignment systems are preferably used, which align the carrier substrate and product substrate with one another with the aid of alignment marks.

In a second process step, the carrier substrate is contacted relative to the product substrate. The contacting can take place either immediately over the whole area or by a point-contact. A fusion bonding system is preferably used.

In a third process step, the carrier base substrate is separated along with the release layer from the growth layer with the aid of a debonding process, in particular with the aid of a laser. The growth layer acts as a barrier with respect to the graphene layer. The growth layer is preferably designed such that the employed debonding process, in particular the laser, does not impair, in particular does not destroy, the transfer layer or the graphene layer. The layer structure thus becomes a new feature in contrast with the prior art. The individual possible debonding processes are described in detail below.

### Debonding Process

In a first, preferred debonding process, electromagnetic radiation, in particular a laser, is used. The carrier base substrate is at least partially transparent for electromagnetic radiation, whilst the release layer preferably exhibits maximum absorption. The growth layer is also absorbing in respect of electromagnetic radiation, so that the latter, in particular the photons which have not been absorbed by the release layer, are prevented from penetrating to the following transfer layer or graphene layer.

The release layer preferably has a high solubility for water. Accordingly, the use of a microwave source for the local introduction of heat through the capacitive heating of the water would be a further conceivable option for debonding.

In a second, less preferred debanding process, the release layer is acted upon by an electric and/or magnetic field. The release layer is then designed such that, when a specific electric and/or magnetic field strength is exceeded, a physical effect occurs leading to a detachment of the release layer and/or to a reduction in the adhesion of the release layer to the growth layer and/or to the first substrate.

In a third, least preferred debonding process, use is made of heat. The heat source is located preferably on the side of the carrier base substrate. A heat sink, in particular active cooling, is preferably located on the side of the product base substrate. The heat is preferably transported up to the release layer, in order to bring about there a separation between the carrier substrate or the release layer and the growth layer. The thermal loading of the transfer layer or of the graphene layer is preferably minimal. Accordingly, the growth layer should in this case be designed such that it is a poor heat conductor and ideally also a poor heat accumulator. This embodiment is less preferred, since a thermal expansion of the different layers of the layer system takes place due to the generation of a raised temperature. Generally, each layer has a different thermal expansion coefficient. If the release layer is polymer-based, a thermal stress can be relieved by flow, but other layers of the layer system are much more susceptible to thermal stresses.

In a fourth process step, it is possible to proceed with the growth layer in different ways.

In a first variant of the fourth process step, the growth layer is simply removed, so that the transfer layer or the graphene layer is exposed. The removal can take place by a chemical and/or physical process. The removal of the growth layer is in particular indispensable when the transfer layer or the graphene layer has to be structured only after the layer transfer.

In a second variant of the fourth process step, the growth layer is structured by a plurality of process steps in order to serve as an etching mask for the transfer layer or the graphene layer lying beneath. After the etching of the transfer layer or the lzraphene layer, the now structured etching layer can be completely removed, since it is no longer required as an etching mask.

In a third variant of the fourth process step, the growth layer itself is left and, insofar as necessary, structured as a functional layer above the transfer layer or the graphene layer. Since, in the vast majority of cases, the growth layer is a conductor, i.e. a conductive, in particular metallic layer, which would short-circuit a possibly structured transfer layer or graphene layer over, in particular, the entire surface, it will be removed in the majority of cases.

In another embodiment, the debonding method is a simple mechanical separation. The two substrates are fixed in such a way that, when at least one of the two substrates is acted upon, a stress, preferably a tensile stress, arises between the release layer and the growth layer, so that the release layer is separated from the growth layer. It would of course be more advantageous if the separation were to take place between the transfer layer and the growth layer. In this case, a release layer could be completely dispensed with, Furthermore, the growth layer would not need to be removed from the transfer layer in further process steps. However, the adhesion between the transfer layer and the growth layer is usually very strong, so that this preferred case will almost never occur. The force to be exerted to separate the two substrates from one another is preferably applied over a small area, in particular in a point-like manner, in particular at at least one point of the periphery of the substrates. The force is greater than 0.01 N, preferably greater than 0.1 N, still more preferably greater than 1 N, most preferably greater than 10 N, with utmost preference greater than 100 N. The mechanical separation can take place particularly easily if a predetermined breaking point is produced in the release layer. The predetermined breaking point can be produced with a blade, in particular a razor blade, a wire or a nozzle, which presses a fluid onto the release layer.

However, the use of electromagnetic radiation is particularly preferred for the debonding. In particular, the use of a laser as a debonding means is the preferred method for debonding. In this case, the carrier substrate should have as great a transparency as possible, more precisely transmissivity, for the used electromagnetic radiation. The carrier substrate is preferably a glass substrate, most preferably a sapphire substrate. The transparency should be described by the transmittance, which indicates the ratio of the transmitted and irradiated radiation. The transmittance is however dependent on the thicknesses of the irradiated body and is not therefore a material-specific property. The values of the transmittance are indicated related to a unit length of 1 cm. In relation to a selected thickness of 1 cm and for the wavelength selected in each case, the material in particular has a transmittance greater than 10%, preferably greater than 20%, still more preferably greater than 50%, most preferably greater than 75%, with utmost preference greater than 99%.

### BRIEF DESCRIPTION OF THE DRAWINGS

Further advantages, features and details of the invention emerge from the following description of preferred examples of embodiment and with the aid of the drawings, In the figures, diagrammatically:

FIG. 1 shows a first embodiment of a carrier substrate according to the invention,

FIG. 2 shows a second embodiment of a carrier substrate,

FIG. 3 shows a first embodiment of a product substrate,

FIG. 4 shows a second embodiment of a product substrate,

FIG. 5 shows a third embodiment of a product substrate,

FIG. 6a shows a first process step of a first method according to the invention,

FIG. 6b shows a second process step of a first method according to the invention

FIG. 6c shows a third process step of a first method according to the invention and

FIG. 6d shows a fourth process step of a first method according to the invention.

### DETAILED DESCRIPTION OF THE INVENTION

Identical components or components with the same function are denoted by the same reference numbers in the figures.

In the figures, the representation of unnecessary components, in particular of substrate holders, is completely dispensed with, since they are not necessary for describing the process. The figures and the individual parts of the representations are not true to scale. The figures are made more comprehensible by the representation not being true to scale. In particular, transfer layer 6, which is described below by way of example in the form of a graphene layer 6, is shown very thick, although it is only a monoatomic layer. In addition, protective layer 5 or growth layer 5 is shown as one layer in the figures. This is the preferred embodiment, in which protective layer 5, apart from the protection, is also designed as a growth layer 5. At all events, a protective layer 5 is provided. It is however also conceivable to arrange an additional growth layer on protective layer 5 in order to generate transfer layer 6. However, a layer with the protection function is preferred which is also suitable for generating or growing a transfer layer 6.

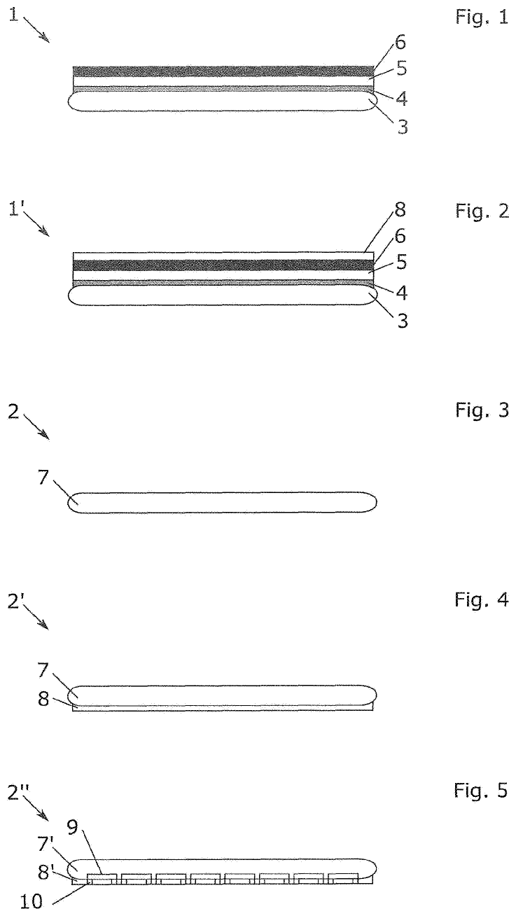

FIG. 1 shows a carrier substrate 1 with a produced layer system in a first embodiment. The layer system comprises a release layer 4, which is applied on carrier base substrate 3. Located on release layer 4 is a growth layer 5 or a protective layer 5. Growth layer 5 has itself preferably been transferred by a layer transfer process onto release layer 4 or has been deposited directly on release layer 4 by a physical or chemical deposition process. A transfer layer 6 or graphene layer 6 has been generated on growth layer 5. The thicknesses of carrier base substrate 3, release layer 4, growth layer 5 and in particular graphene layer 6 are not represented true to scale. In particular, graphene layer 6 as a monoatomic layer should have been represented very much thinner, in particular only as a single line. In order to improve the representation, a representation true to scale has however been dispensed with.

FIG. 2 shows a carrier substrate 1′ with a produced layer system in a second embodiment. Carrier substrate 1′ has a deposited or transferred contact layer 8 on transfer layer 6 or graphene layer 6.

FIG. 3 shows a product substrate 2 in a first embodiment. Product substrate 2 in particular comprises only product base substrate 7.

FIG. 4 shows a product substrate 2′ in a second embodiment. Product substrate 2′ comprises only product base substrate 7 and a contact layer 8 deposited or transferred thereon. Contact layer 8 is preferably a dielectric layer, most preferably a silicon oxide layer.

FIG. 5 shows a product substrate 2″ in a third embodiment. Product substrate 2″ comprises a product base substrate 7′. In particular, functional components 9 have already been produced in product base substrate 7′. Contact layer 8′ has preferably been deposited above product base substrate 7′. Contact layer 8′ preferably comprises electrically conductive through-contact vias 10, which are intended to connect the, in particular functional, components 9 to the transfer layer to be transferred or the graphene layer (not shown). This embodiment would also be conceivable without contact layer 8′. In this case, through-contact vias 10 would also be absent and a transferred transfer layer or graphene layer (not shown) would directly contact contact points of the, in particular functional, component 9 (not shown). Contact layer 8′ is once again preferably a dielectric layer, most preferably a silicon oxide layer.

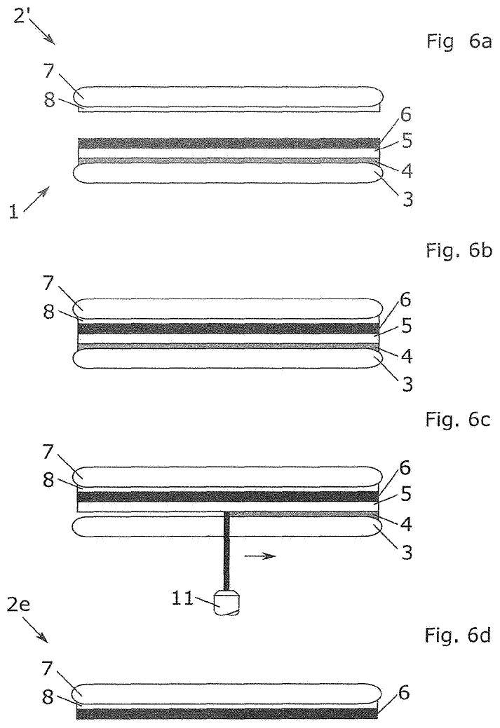

The following FIGS. 6a to 6d show a first method or a process for transferring a transfer layer by way of example with the aid of a carrier substrate 2′ and a product substrate 2′. The process can however be carried out by any carrier substrate-product substrate combination, in particular also by carrier substrates and/or product substrates which are not explicitly, represented, inasmuch as the layer system, comprising release layer 4, growth layer 5 and transfer layer 6 to be transferred or graphene layer 6, are present in this sequence.

Furthermore, in the following figures product substrate 2′ is represented at the upper side and carrier substrate 1′ at the underside. It is also conceivable for carrier substrate to be located at the upper side and product substrate 1′ at the underside. For the sake of clarity, the representation of substrate holders, bonding devices and alignment devices is dispensed with.

FIG. 6a shows a first process step of a first method or a first process for transferring a transfer layer, wherein a product substrate 2′, comprising a product base substrate 7 and a contact layer 8′, is aligned relative to a carrier substrate 1. Contact layer 8 is preferably an oxide, most preferably a silicon oxide. Carrier substrate 1 comprises a carrier base substrate 3, a release layer 4, a growth layer 5, as well as transfer layer 6 or graphene layer 6 to be transferred. How graphene layer 6 has been generated or has been transferred on growth layer 5 is not relevant for an understanding of the process and will not therefore be described in greater detail. The alignment can take place mechanically and/or optically. In the case of an optical alignment, alignment marks (not shown) in particular are present on product substrate 2′ and on carrier substrate 1.

FIG. 6b shows a second process step of the first process, wherein contacting between carrier substrate 1 and product substrate 2′ takes place. It is not represented in the figure how the contacting precisely takes place, since it is not relevant for the process. The contacting preferably takes place, however, by means of a device in which at least one of the two substrates 1, 2′ is curved. The contacting process is therefore preferably carried out with the aid of a fusion bonding system. In a very particularly preferred embodiment of the process, the, in particular upper, product substrate 2′ is curved, whereas the, in particular lower, carrier substrate 1 is fixed over the entire area.

FIG. 6c shows a third process step of the first process. Release layer 4 is acted upon by a debonding means 11. Debonding means is preferably a laser. The debonding means preferably acts via carrier base substrate 3 on release layer 4. Growth layer 5 acts as a protective shield for graphene layer 6 lying behind. Since graphene layer 6 is a rnonoatomic layer, graphene layer 6 could be destroyed by debonding means 11 with high intensities. Growth layer 5, which is preferably also used to generate graphene layer 6, is therefore used as a protective shield. Growth layer 5 thus has to be designed in such a way that bonding means 11 used in each case is blocked in the best possible way during the debonding process or influences on transfer layer 6 arising from debonding means 11 are at least very markedly reduced. If debonding means 11 is a laser, growth layer 5 should have a transmissivity as low as possible for the photons of laser 11. If debonding means 11 involves for example heat which is introduced by a heat source, growth layer 5 should have a thermal conductivity as low as possible, in order to make the transport of heat to graphene layer 6 difficult.

It is clear to the expert in the field that an arbitrary number of other layers can be present between release layer 4 and growth layer 5, which can perform the particular function of protection of transfer layer 6. Thus, it would be conceivable to insert a further layer between release layer 4 and growth layer 5, which further layer absorbs the laser radiation or heat of a debonding means 11 extremely well. For the sake of simplicity, however, this property is combined in a single growth layer 5, in order not to complicate either the description or the representation. In particular, it is advantageous if growth layer 5, which is preferably used for the growth of graphene layer 6, at the same time also serves as its protective layer for used debonding means 11. A very cost-effective process can thus be carried out, because it is not necessary to deposit further expensive layers. A further advantage includes the fact that growth layer 5 is particularly preferably a metal layer, most preferably a nickel layer. As is known, metals are very good infrared absorbers. The most preferred debonding means 11 is a laser, preferably an infrared laser. Metallic growth layer 11, in this special case on account of its solid state properties, can thus serve simultaneously as growth layer 5 and as a protective layer. If debonding means 11 were a heat source, a metallic rowth layer 5 would of course be less than optimal on account of the relatively high thermal conductivity. In this case, further layers are preferably inserted between growth layer 5 and release layer 4, in particular ones with low thermal conductivity.

FIG. 6d shows a first variant of a fourth process step of the first process, wherein also transferred growth layer 5 (no longer shown) has already been removed. A transfer layer 6 or a graphene layer 6 is obtained on a product substrate 2e, which represents the end product of the process. Product substrate 2e, in particular transferred graphene layer 6, can then be further processed in further process steps. The two other variants for the use of growth layer 5, which have already been mentioned, are no longer represented graphically here, since no further conclusions concerning the actual process can be drawn from them.

### LIST OF REFERENCE NUMBERS

1 carrier substrate

2, 2′, 2″, 2e product substrate

3 carrier base substrate

4 release layer

5 growth layer, protective layer

6 transfer layer, gra.phene layer

7, 7′ product base substrate

8, 8′ contact layer

9 functional units

10 through-contact vias

11 debonding means

1.-15. (canceled)

16. A carrier substrate for transferring a transfer layer from the carrier substrate to a product substrate, comprising:
a plurality of layers, the layers comprising, in sequence:
a carrier base substrate;
a protective layer; and
the transfer layer,
wherein at least one release layer is arranged between the carrier base substrate and the protective layer,
wherein the transfer layer is grown on the protective layer, and
wherein the protective layer shields the transfer layer.

17. The carrier substrate according to claim 16, wherein the transfer layer is a graphene layer.

18. The carrier substrate according to claim 16, wherein a roughness of the protective layer on a surface facing the transfer layer is less than 100 μm.

19. The carrier substrate according to claim 16, wherein the transfer layer comprises at least one release layer arranged between the carrier base substrate and the protective layer.

20. The carrier substrate according to claim 19, wherein the transfer layer is detachable from the carrier base substrate together with the protective layer by means of a debonding means acting on one or more of the release layer and a release area.

21. The carrier substrate according to claim 16, wherein the protective layer comprises a material with a solubility for carbon.

22. The carrier substrate according to claim 16, wherein the protective layer is impermeable to electromagnetic radiation.

23. The carrier substrate according to claim 16, wherein a contact layer made of a dielectric material is arranged on a side of the transfer layer facing away from the protective layer.

24. The carrier substrate according to claim 16, wherein the protective layer is a monocrystalline metal layer.

25. A method for the production of a carrier substrate for transferring a transfer layer from the carrier substrate onto a product substrate, comprising:
providing a carrier base substrate;
applying a protective layer on the carrier base substrate; and
growing the transfer layer on the protective layer.

26. The method according to claim 25, wherein the protective layer is recrystallised before the growing of the transfer layer.

27. The method according to claim 25, wherein the carrier base substrate is coated with a release layer before the applying of the protective layer so that the protective layer is applied on the release layer.

28. The method according to claim 25, wherein a contact layer is deposited on the transfer layer on a side of the transfer layer facing away from the protective layer.

29. The method according to claim 25, wherein the carrier substrate is contacted by the product substrate, so that the transfer layer is facing the product substrate, and
wherein at least one debonding means acts on the carrier substrate, so that the transfer layer together with the protective layer is detached from a carrier base substrate.

30. The method according to claim 28, wherein the carrier substrate is contacted by the product substrate via a contact layer applied on the transfer layer.

31. The method according to claim 29, wherein the carrier substrate is contacted by a further contact layer of the product substrate applied on a product base substrate via the contact layer applied on the transfer layer.

32. The carrier substrate according to claim 18, wherein the roughness of the protective layer on the surface facing the transfer layer is less than 10 μm.

33. The carrier substrate according to claim 31, wherein the roughness of the protective layer on the surface facing the transfer layer is less than 1 μm.

34. The carrier substrate according to claim 24, wherein the monocrystalline metal layer is made of nickel.

35. The method according to claim 25, wherein the transfer layer is a graphene layer.
